(19) United States
(12) Patent Application Publication
(10) Pub. No.: US 2024/0371914 A1
(43) Pub. Date: Nov. 7, 2024

(54) BOND WIRE INDUCTION APPARATUS

(71) Applicant: Micron Technology, Inc., Boise, ID (US)

(72) Inventors: Carlos Franco, Boise, ID (US); Dale Arnold, Meridian, ID (US); Dan Soto, Boise, ID (US)

(21) Appl. No.: 18/652,081

(22) Filed: May 1, 2024

Related U.S. Application Data
(60) Provisional application No. 63/463,431, filed on May 2, 2023.

(51) Int. Cl. H01L 25/18; H10B 80/00; H01L 23/00

(52) U.S. Cl. CPC H01L 28/10; H01L 25/18; H10B 80/00; H01L 24/48; H01L 2224/48091; H01L 2224/48145; H01L 2924/1433; H01L 2924/14511

(57) ABSTRACT

Systems, methods, and apparatus are provided for a bond wire induction apparatus. A particular induction apparatus can include a memory package comprising a substrate and a plurality of memory layers, a plurality of conductive nodes connected by a plurality of conductive traces to form a first portion of an induction device. In this embodiment, the first portion of the inductive device comprises an inductive coil within at least two layers of the plurality of memory layers of the memory package. In addition, the apparatus can include a plurality of bond traces to couple a first portion of the plurality of conductive nodes to a second portion of the plurality of conductive nodes to form a second portion of the inductive device, such that the second portion of the inductive device comprises an inductive bond wire in a physical area that is physically outside the memory package.

### TECHNICAL FIELD

This application claims the benefits of U.S. Provisional Application No. 63/463,431, filed on May 2, 2024, the contents of which are incorporated herein by reference.

### TECHNICAL FIELD

The present disclosure relates generally to integrated circuits, and more particularly to a bond wire induction apparatus.

### BACKGROUND

A memory system can include digital logic and an associated power supply, voltage control, and clock control. In general, the power supply, voltage control, and/or clock control can change a voltage or frequency during operation of the digital logic. Voltage converters can be utilized to alter an input voltage to an output voltage that is different from the input voltage. Some voltage converters can utilize an inductor.

### BRIEF DESCRIPTION OF THE DRAWINGS

FIG. 1 illustrates a bond wire induction apparatus in accordance with a number of embodiments of the present disclosure.

FIG. 2 illustrates a bond wire induction system in accordance with a number of embodiments of the present disclosure.

FIG. 3 illustrates a portion of a bond wire induction system in accordance with a number of embodiments of the present disclosure.

FIG. 4 illustrates a portion of bond wire induction systems in accordance with a number of embodiments of the present disclosure.

FIG. 5 is a flow diagram corresponding to a method for forming a bond wire induction apparatus in accordance with a number of embodiments of the present disclosure.

FIG. 6 illustrates a memory system utilizing a bond wire induction apparatus in accordance with a number of embodiments of the present disclosure.

### DETAILED DESCRIPTION

Embodiments of the present disclosure describe a bond wire induction apparatus. The bond wire induction apparatus can be used in an integrated circuit, for instance. The bond wire induction apparatus can be utilized with a direct current to direct current (DC/DC) boost converter for a memory device. In some embodiments, the bond wire induction apparatus can be utilized in conjunction with a conductive node induction apparatus. For example, the bond wire induction apparatus can be aligned along a surface of a conductive node induction apparatus. In this way, the conductive node induction apparatus can generate a first induction and the bond wire induction apparatus can generate a second induction. In these embodiments, the first induction and the second induction can be utilized with a DC/DC boost converter. A DC/DC boost converter can be a power converter that steps up voltage while stepping down current from an input supply to an output. In some embodiments the memory device can utilize a DC/DC boost converter to improve efficiency of increasing the voltage compared to utilizing a charge pump.

Utilizing a DC/DC boost converter can be disadvantageous when utilized with a memory device due to particular size restrictions of the memory device and the utilization of an inductor (e.g., induction apparatus, etc.). For example, the induction apparatus may be restricted to a particular size when utilized with a NAND type memory device. Although embodiments of utilizing the bond wire induction apparatus as part of a DC/DC boost converter are described herein, the present disclosure is not so limited. For example, the bond wire induction apparatus described herein can be utilized with other types of systems and circuits that utilize induction to oppose a change of current.

In some embodiments, when a DC/DC boost converter is utilized for a memory device, the components of the DC/DC boost converter, such as an induction apparatus, can be implemented within a substrate of a memory package (e.g., substrate, layer of a substrate, ASIC package, etc.). As used herein, the term “package” generally refers to a collection of one or more memory dice. The substrate of the memory device can be utilized to protect the integrated circuits or other components of the memory device. In some embodiments, the component size restrictions can be further restricted when implementing or embedding the components within the substrate or between layers of the substrate. The size restrictions of the induction apparatus can lower the output voltage of the DC/DC boost converter when utilizing a traditional induction apparatus, such as a square induction device. That is, decreasing the size or physical dimensions of a traditional induction device can lower the output voltage to a level that is below a target voltage for the memory device. In this way, the design parameters of a traditional induction device may not be usable when the induction device is an on-chip inductor, an on-interposer inductor, and/or an on-board inductor.

The present disclosure addresses several issues present in some traditional induction devices. With traditional spiral induction devices (e.g., square inductors, etc.) a conductive line can be routed in a square or spiral shape surrounding a core. In this way, a voltage can be provided to the induction device to generate a magnetic field which can resist a current change. This resistance to current change can allow for the DC/DC boost converter to alter an input voltage to an increased output voltage. However, the inductance provided by the spiral induction devices or other previous types of planar induction devices may not be high enough or may have a Q-factor below a threshold Q-factor for the memory device when the overall size of the induction device is reduced. As will be appreciated, the term “Q-factor” generally refers to the ratio of the inductive resistance to the resistance for an inductor (e.g., the conductive node induction system described here) at a given frequency. For example, the thickness of the conductive lines may be limited due to height restrictions and the quantity of spirals around a core can be limited due to area restrictions.

In contrast to the traditional induction coil devices previously discussed, the conductive node induction apparatus along with the bond wire induction apparatus of the present disclosure can be used within smaller special restrictions while still providing greater inductance and a greater Q-factor than the traditional induction devices. The conductive node induction apparatus is a coreless induction apparatus that utilizes a first plurality of conductive nodes that are aligned parallel to a second plurality of conductive nodes. In these embodiments, the first and second plurality of conductive nodes each include a first conductive edge (e.g., top edge, etc.) and a second conductive edge (e.g., bottom edge, etc.). In these embodiments, conductive traces can connect a first conductive edge of a first conductive node of the first plurality to a second conductive edge of a second conductive node of the second plurality. This can be continued along the first plurality of conductive nodes and the second plurality of conductive nodes to generate a conductive node induction apparatus formed by the coil generated between the first plurality of conductive nodes and the second plurality of conductive nodes by the conductive traces. The conductive node apparatus can provide parasitic capacitance above 1 gigahertz and a Q-factor above 5 when utilizing a switching frequency at or near 50 megahertz, although embodiments are not limited to providing these enumerated values.

In addition to the inductance generated by the conductive node induction apparatus, a bond wire induction apparatus can be utilized to generate an additional inductance. As described herein, the inductance from the conductive node induction apparatus can be utilized with the inductance from the bond wire induction apparatus by a DC/DC boost converter. In some embodiments, a bond wire induction apparatus can generate an induction loop that extends from a first conductive node to a second conductive node of the conductive node induction apparatus. In this way, a first induction coil of the conductive node apparatus is formed within a substrate and a second induction coil of the bond wire induction apparatus is formed outside the substrate. As described further herein, the bond wire induction apparatus can include a plurality of parallel bond traces that couple a first conductive node to a second conductive node of the conductive node induction apparatus. As used herein, the parallel bond wires can be a plurality of bond traces to form each of a plurality of coils of the bond wire induction apparatus. Although specific examples of a conductive node induction apparatus are described herein, other types of induction devices can be utilized with the bond wire induction apparatus in as a similar way.

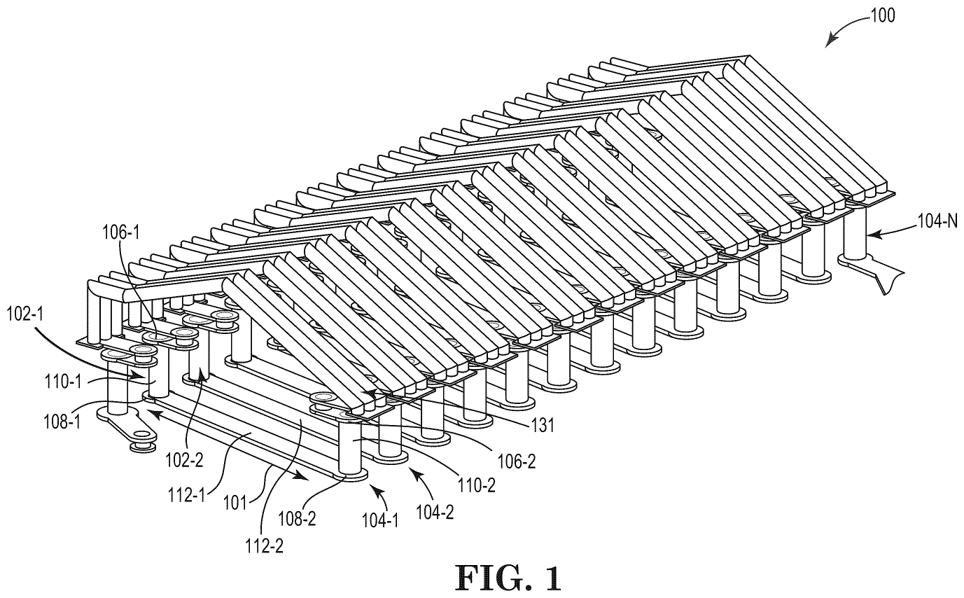

FIG. 1 illustrates a bond wire induction apparatus 100 in accordance with a number of embodiments of the present disclosure. The conductive node induction apparatus can be a planar inductor positioned within a substrate. The conductive node induction apparatus can be a bottom portion of the bond wire induction apparatus 100 such that the bond wire induction portion is positioned outside of the substrate while the conductive node induction apparatus is positioned within the substrate. The bond wire induction apparatus 100 can be utilized to generate inductance when a voltage is applied to the conductive node induction apparatus. As described herein, inductance is the ratio of the voltage to the rate of change of current. Inductance can be utilized by a DC/DC boost converter to convert an input voltage to a greater output voltage. Although a DC/DC boost converter is used as a specific example for utilizing the bond wire induction apparatus 100, this disclosure is not so limited. That is, the bond wire induction apparatus 100 can be utilized by other devices or systems that utilize traditional inductor devices.

The bond wire induction apparatus 100 can include a first plurality of conductive nodes 102-1, 102-2, 102-N (collectively referred to herein as the first plurality of conductive nodes 102). In addition, the bond wire induction apparatus 100 includes a second plurality of conductive nodes 104-1, 104-2, 104-N (collectively referred to herein as the second plurality of conductive nodes 104). In some embodiments, the first plurality of conductive nodes 102 can be separated from the second plurality of conductive nodes 104 by a space 101. The space 101 can be utilized as a conductive separation between the first plurality of conductive nodes 102 and the second plurality of conductive nodes 104. In a specific example, the space 101 can be between approximately 1 millimeter (mm) and 2 mm, although other distances for the space 101 can also be utilized.

In some embodiments, the first plurality of conductive nodes 102 can be substantially parallel to the second plurality of conductive nodes 104 with the space 101 being maintained between the first plurality of conductive nodes 102 and the second plurality of conductive nodes 104. In this way, the distance of the space 101 can be maintained from the first end of the conductive node induction apparatus 100 to the second end of the conductive node induction apparatus 100. As used herein, the term “substantially” intends that the characteristic need not be absolute, but is close enough so as to achieve the advantages of the characteristic. For example, “substantially parallel” is not limited to characteristics that are absolutely parallel and can include characteristics that are intended to be parallel but due to manufacturing limitations may not be precisely parallel.

The first plurality of conductive nodes 102 can each include a first conductive edge 106-1 and a second conductive edge 108-1. The first conductive edge 106-1 can be coupled to the second conductive edge 108-1 by an interior portion 110-1. In these embodiments, the interior portion 110-1 can be a conductive material with a first diameter. The first conductive edge 106-1 can be coupled to a first side of the interior portion 110-1 and the second conductive edge 108-1 can be coupled to a second side of the interior portion 110-1. In these embodiments, the first conductive edge 106-1 and the second conductive edge 108-1 can have a second diameter that is larger than the first diameter of the interior portion 110-1. In this way, the first conductive edge 106-1 and the second conductive edge 108-1 can be surfaces that can be utilized to be coupled to conductive traces 112-1, 112-2, 112-N (collectively referred to as conductive traces 112).

In some embodiments, the conductive traces 112 cross the space 101 between the first plurality of conductive nodes 102 and the second plurality of conductive nodes 104. In some embodiments, the conductive traces 112 can have a width that is less than 100 micrometers. In a specific example, the conductive traces 112 can have a width that is approximately 65 micrometers. In these embodiments, the space 101 can be a distance between 1.0 millimeters and 2.0 millimeters. In a specific example, the space 101 can be 1.3 millimeters.

In a similar way, the second plurality of conductive nodes 104 can each include a corresponding first conductive edge 106-2, second conductive edge 108-2, and interior portion 110-2. In this way, the first plurality of conductive nodes 102 can be coupled to the second plurality of conductive nodes by utilizing the conductive traces 112. In some embodiments, the second conductive edges 108-1 of the first plurality of conductive nodes 102 can be coupled to corresponding second conductive edges 108-2 of the second plurality of conductive nodes 104.

The conductive traces 112 can be a conductive material such as, but not limited to a copper material. In some embodiments, the conductive traces 112 can be a copper material to carry an electrical current from the first plurality of conductive nodes 102 to the second plurality of conductive nodes 104 and back to the first plurality of conductive nodes 102. In this way, the electrical current can flow through a coil created by the first plurality of conductive nodes 102, second plurality of conductive nodes 104, and conductive traces 112. In some embodiments, the conductive traces 112 can be a copper material that includes a width or thickness that is approximately between 50 micrometers and 100 micrometers. In a specific example, the conductive traces 112 are a copper material that includes a width that is approximately 65 micrometers.

In some embodiments, the bond wire induction apparatus 100 can include a plurality of bond traces 131. As described further herein, the plurality of bond traces 131 can be formed as arches above the conductive node induction apparatus. In these embodiments, the plurality of bond traces can be utilized to couple a first conductive edge 106-1 of a first conductive node 102-1 to a corresponding conductive edge 106-2 of a second conductive node 104-1. In this way, a loop can be formed through the conductive traces 112 of the conductive node apparatus and the bond traces 131 of the bond wire induction apparatus 100.

As described herein, the bond wire induction apparatus 100 is a coreless induction apparatus. In traditional induction devices, a metal core can be utilized as an interior element where the conductive traces are wrapped around to create the coil that creates the inductance. The coreless design utilized by the bond wire induction apparatus 100 can reduce the footprint and/or overall dimensions occupied by the bond wire induction apparatus 100 while providing an increased inductance and increased Q-factor compared to traditional induction devices that are restricted to a similar footprint.

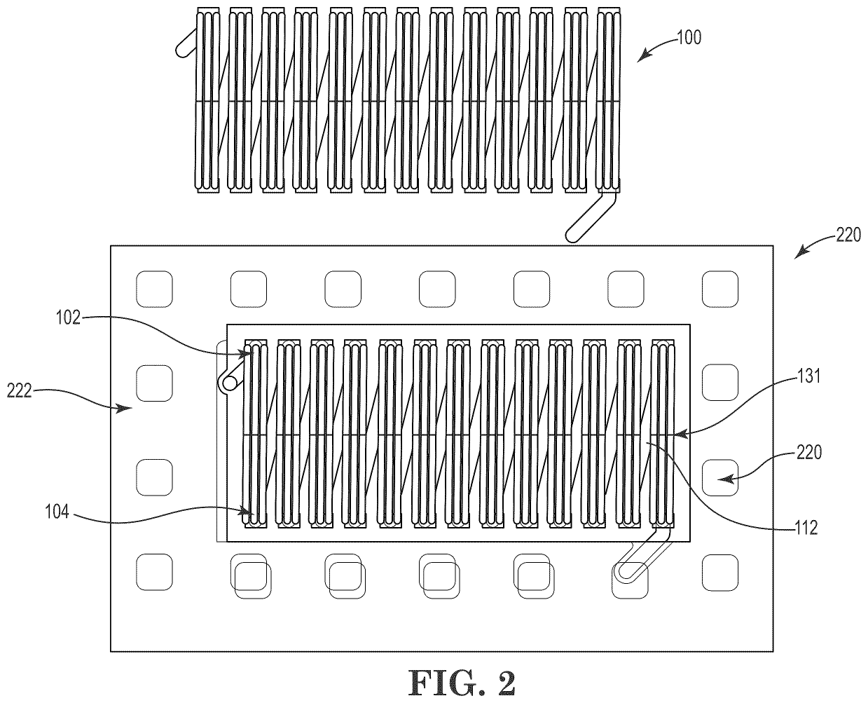

FIG. 2 illustrates a bond wire induction system 220 in accordance with a number of embodiments of the present disclosure. In some embodiments, the system 220 illustrates the bond wire induction apparatus 100 embedded between a first layer of a substrate 222 and a second layer of the substrate 222. FIG. 2 illustrates the bond wire induction apparatus 100 from a top view. For example, the bond wire induction apparatus 100 can be illustrated from a top view such that the top conductive edges of the first plurality of conductive nodes 102 and the top conductive edges of the second plurality of conductive nodes 104 are illustrated.

As illustrated in FIG. 2, the bond wire induction apparatus 100 can include a first plurality of conductive nodes 102 aligned across from a second plurality of conductive nodes 104. The first plurality of conductive nodes 102 can be coupled to the second plurality of conductive nodes 104 by a plurality of conductive traces 112. As described herein, the plurality of conductive traces 112 can connect a second conductive edge of the first plurality of conductive nodes 102 to a second conductive edge of the second plurality of conductive nodes 104. In addition, a plurality of bond traces 131 can connect a first conductive edge of the first plurality of conductive nodes 102 to a first conductive edge of the second plurality of conductive nodes 104. In this way, the plurality of conductive traces 112 and bond traces 131 can connect conductive edges of the first plurality of conductive nodes 102 and the second plurality of conductive nodes 104 to form a coil that is utilized as the bond wire induction apparatus 100.

The first layer and/or the second layer of the substrate 222 can be a metal material that can be utilized as an electrical ground for the system 220. For example, the first layer and the second layer of the substrate 222 can be a copper material that can be an electrical ground for the system 220. In some embodiments, the first layer can be aligned parallel or substantially parallel to a first conductive edge of the first plurality of conductive nodes 102 and the first conductive edge of the second plurality of conductive nodes 104. In a similar way, the second layer can be aligned parallel or substantially parallel to the second conductive edge of the first plurality of conductive nodes 102 and the second conductive edge of the second plurality of conductive nodes 104. That is, a conductive trace portion of the bond wire induction apparatus 100 can be positioned between the first layer and the second layer of the substrate 222 while the bond wire portion can be positioned above or outside the substrate 222.

In some embodiments, the first layer and the second layer of the substrate 222 can include a plurality of apertures 224. The apertures 224 can be cut-out or removed portions of the material of the first layer and the second layer. In some embodiments, the plurality of apertures 224 can be a particular shape (e.g., circle, triangle, diamond, etc.). In some embodiments, the plurality of apertures 224 can reduce electromagnetic interference (EMI) radiation generated by the bond wire induction apparatus 100. In these embodiments, the EMI radiation can be unwanted noise that can be generated by the bond wire induction apparatus 100. In some embodiments, the plurality of apertures 224 can reduce capacitive parasitic effects associated with operation of the bond wire induction apparatus 100. In some embodiments, the plurality of bond traces 331 can form an arc above an aperture 224 of the memory package 222.

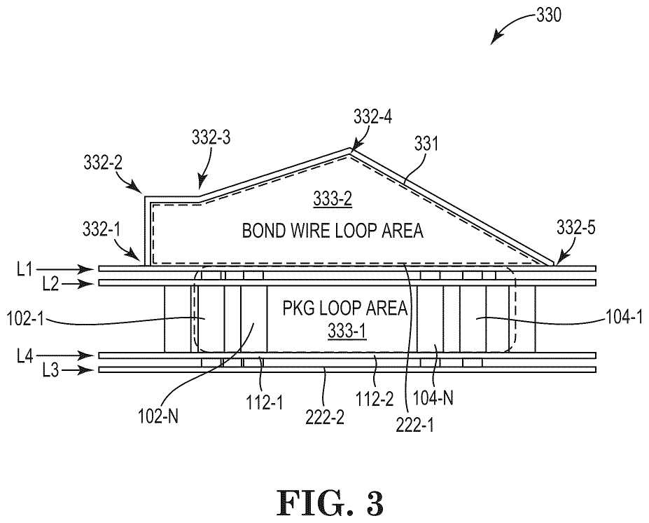

FIG. 3 illustrates a portion of a bond wire induction system 330 in accordance with a number of embodiments of the present disclosure. The bond wire induction system 330 can include the same or similar elements as the bond wire induction apparatus 100 as referenced FIG. 1 and/or the bond wire induction system 220 as referenced in FIG. 2. The bond wire induction system 330 can include a package loop area 333-1 that can be formed by a conductive node induction apparatus as referenced in FIG. 1. In addition, the bond wire induction system 330 can include a bond wire loop area 333-2 that can be formed by a single bond trace 331 or a plurality of bond traces.

As described herein, the package loop area 333-1 can be formed by a first plurality of conductive nodes 102-1, 102-N coupled to a second plurality of conductive nodes 104-1, 104-N by a plurality of conductive traces 112-1, 112-2. In some embodiments, the package loop area 333-1 includes a first surface formed by a first conductive trace 112-1 and a second surface formed by a second conductive trace 112-2. In these embodiments, the first surface formed by the first conductive trace 112-1 or a first plurality of conductive traces can be parallel to a first layer 222-1 of a substrate and the second surface formed by the second conductive trace 112-2 or plurality of conductive traces can be parallel to a second layer 222-2 of a substrate. In this way, the package loop area 333-1 can be formed between the first layer 222-1 of the substrate and the second layer 222-2 of the substrate.

In some embodiments, the first conductive trace 112-1 and/or a first plurality of conductive traces can be formed along an interior surface of a first layer 222-1 of the substrate. Although a single package loop area 333-1 and a single bond wire loop area 333-2 are illustrated in FIG. 3, additional layers of package loop areas and bond wire loop areas can be utilized.

In some embodiments, the bond wire loop area 333-2 can be formed on an exterior surface of the first layer 222-1 of the substrate and/or the exterior surface of the second layer 222-2 of the substrate. In this way, the bond wire loop area 333-2 can be formed outside of the substrate of the memory package. As described herein, a first quantity of inductance can be generated by the conductive node induction apparatus within the package loop area 333-1 and a second quantity of inductance can be generated by the bond wire induction apparatus within the bond wire loop area. In this way, the first inductance and the second inductance can be utilized by a DC/DC boost converter or other device utilizing inductance.

In some embodiments, the bond trace 331 can include a plurality of parallel bond traces positioned to form the bond wire loop area 333-2. As described further herein, the bond trace 331 can include a conductive material that is similar or the same material as the plurality of conductive traces 112-1, 112-N such that when an electrical voltage or current is applied to the bond trace 331 an induction is generated. In some embodiments, the bond wire loop area 333-2 can be defined by a perimeter of the bond trace 331 and/or a plurality of bond traces. In some embodiments, the bond trace 331 can form an arc over the package loop area 333-1. As used herein, an arc can refer to a curved path with a space between the bond trace 331 and a surface of the package loop area 333-1.

In some embodiments, the bond trace 331 can include a plurality of transition points 332-1, 332-2, 332-3, 332-4, 332-5 (collectively referred to as a plurality of transition points 332). As used herein, a transition point can refer to a point when the bond trace 331 changes in direction or is a vertex of an angle of the bond trace 331. Although five transition points 332 are illustrated, a plurality of additional transition points 332 or fewer transition points 332 can be utilized to generate a coil of the bond wire loop area 333-2. In some examples, a first transition point 332-1 can be coupled to a first conductive node 102-1 to receive electricity from a power source. In this way, the power source can be utilized to provide an electric current through the conductive node induction apparatus of the package loop area 333-1 and the bond wire induction apparatus of the bond wire loop area 333-2.

In some embodiments, the package loop area 333-1 can be formed utilizing a dielectric material to allow the bond trace 331 to be formed into a particular shape as illustrated in FIG. 3. For example, the first transition point 332-1 can be connected to the first conductive node 102-1. In this example, the bond trace 331 can be formed from the first transition point 332-1 to the second transition point 332-1 such that the bond trace 331 is positioned a first distance away from an exterior surface of the first layer 222-1 of the substrate. In this way, the second transition point 332-2 can be a first distance away from the exterior surface of the first layer 222-1 of the substrate. In some examples, the bond trace 331 can be formed from the second transition point 332-2 to a third transition point 332-3. In some embodiments, the third transition point 332-3 can be the same distance or similar distance to the exterior surface of the first layer 222-1 of the substrate as the second transition point 332-3.

In some embodiments, the bond trace 331 can be formed from the third transition point 332-2 to a fourth transition point 332-4. In some embodiments, the fourth transition point 332-4 can be a greater distance from the exterior surface of the first layer 222-1 of the substrate than the second transition point 332-2 and/or the third transition point 332-3. In some embodiments, the fourth transition point 332-4 can be a peak point or peak position of the bond wire loop area 333-2. That is, the fourth transition point 332-4 can be a point with a greatest distance between the bond trace 331 and the exterior surface of the first layer 222-1 of the substrate. In these embodiments, the bond trace 331 can be formed from the fourth transition point 332-4 to a fifth transition point 332-5. In some embodiments, the fifth transition point 332-5 is connected to a second conductive node 104-1. In this way, the electric current can pass from the first conductive node 102-1 to the second conductive node 104-1 through the bond trace 331.

In some embodiments, the length between the first transition point 332-1 and the fifth transition point 332-5 can be greater than the length between the first conductive node 102-1 and the second conductive node 104-1. In this way, the bond wire loop area 333-2 extends beyond a footprint of the package loop area 333-1. That is, the bond trace 331 forms a bond wire loop area 333-2 that extends beyond the first set of conductive nodes 102-1, 102-N and the second set of conductive nodes 104-1, 104-N.

As described herein, the bond wire loop area 333-2 can provide additional induction to the induction generated by the package loop area 333-1 that can be utilized by the bond wire induction system 330. In this way, the bond wire loop area 333-2 can be added to an area outside the package loop area 333-1 to increase an inductance of the bond wire induction system 330 within the same footprint of the package loop area 353-1.

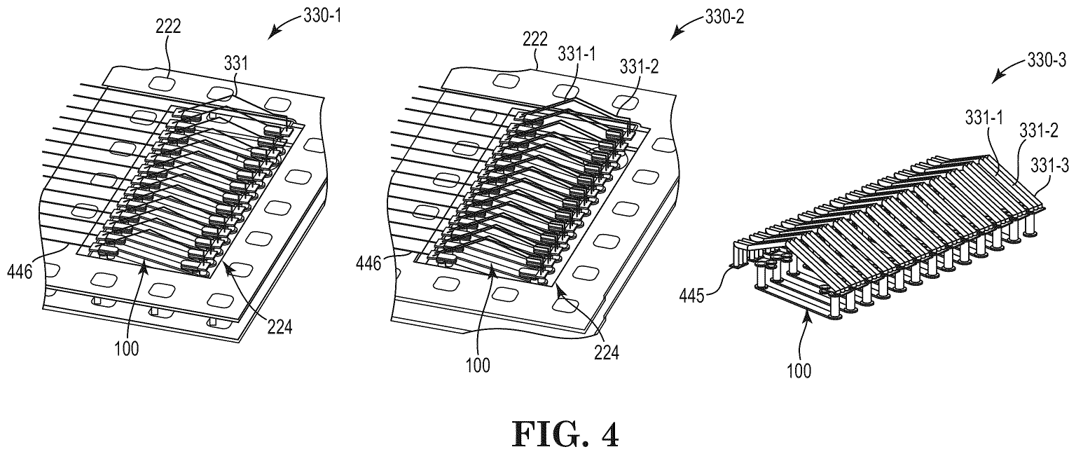

FIG. 4 illustrates a portion of bond wire induction systems 330-1, 330-2, 330-3 in accordance with a number of embodiments of the present disclosure. The bond wire induction systems 330-1, 330-2, 330-3 can include the same or similar elements as the bond wire induction system 330 as referenced in FIG. 3. For example, the bond wire induction systems 330-1, 330-2, 330-3 can each include a substrate 222 that separates a conductive node induction apparatus 100 from a bond wire induction apparatus comprising a number of bond traces 331.

In the bond wire induction system 330-1, the bond trace 331 can be a single bond trace 331 that can be connected to a power source through a connection 445. In these embodiments, the single bond trace 331 can be a conductive material (e.g., electrically conductive, etc.) that can be utilized to generate an inductance from a first conductive node to a second conductive node of the conductive node induction apparatus 100. As described herein, the substrate 222 can include an aperture 224 and/or a plurality of apertures between the conductive node induction apparatus 100 and the bond wire induction apparatus comprising the single bond trace 331. Depending on the type of wire bonding, a wire bonding pad may have a trace 446 exiting the connection 445 for electrolytic plating as required. If a manufacturing process does not require plating for wire bonding, the trace 446 exiting the individual pad connection may not be required and the trace 446 can be eliminated.

The bond wire induction system 330-2 can include a plurality of bond traces 331-1, 331-2. In this embodiment, the bond wire induction system 330-2 can include a first bond trace 331-1 and a second bond trace 331-2. In some embodiments, the first bond trace 331-1 can be parallel or substantially parallel with the second bond trace 331-2. In this way, electricity can be provided to the first bond trace 331-1 and the second bond trace 331-2 independently to generate an inductance. In these embodiments, the parallel bond traces 331-1, 331-2 can generate a relatively greater quantity of inductance compared to a single bond trace 331 from the bond wire induction system 330-1.

The bond wire induction system 330-3 can be illustrated without the substrate 222 to more clearly illustrate the bond wire induction system 330-3. The bond wire induction system 330-3 can include a plurality of bond traces 331-1, 331-2, 331-3. For example, the bond wire induction system 330-3 can include a first bond trace 331-1, a second bond trace 331-2, and a third bond trace 331-3. In these embodiments, the plurality of bond traces 331-1, 331-2, 331-3 can be parallel to each other such that an electrical current can be provided individually to each of the plurality of bond traces 331-1, 331-2, 331-3. In some embodiments, the plurality of bond traces 331-1, 331-2, 331-3 can generate relatively greater inductance compared to the bond wire induction system 330-2.

The bond wire induction systems 330-1, 330-2, 330-3 can be utilized to generate a greater quantity of inductance compared to utilizing only the conductive node apparatus 100. In some embodiments, the bond traces 331-1, 331-2, 331-3 can be formed on an exterior surface of the substrate 222 to generate an inductance that is separate from the conductive node apparatus 100.

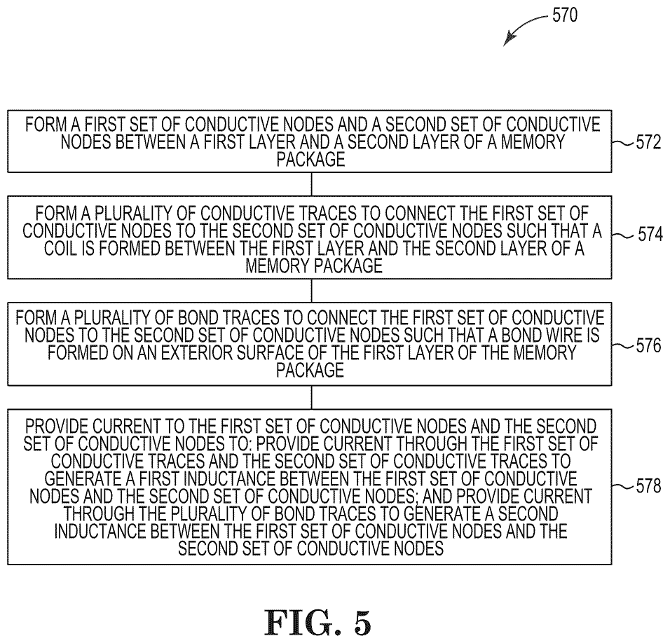

FIG. 5 is a flow diagram corresponding to a method 570 for forming a bond wire induction apparatus in accordance with a number of embodiments of the present disclosure. In some embodiments, the method 570 can be utilized to generate a conductive node induction apparatus 100 as referenced in FIG. 1, a conductive node induction system 220 as referenced in FIG. 2, a bond wire induction system 330 as referenced in FIG. 3, and/or the bond wire induction system 330 as referenced in FIG. 4. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At 572, the method 570 can include forming a first set of conductive nodes and a second set of conductive nodes between a first layer and a second layer of a memory package. In some embodiments, forming the first set of conductive nodes can include forming the first plurality of conductive nodes 102-1, 102-2, 102-N as referenced in FIG. 1. In a similar way, forming the second set of conductive nodes can include forming the second plurality of conductive nodes 104-1, 104-2, 104-N as referenced in FIG. 1. As described herein, the first plurality of conductive nodes 102-1, 102-2, 102-N and the second plurality of conductive nodes 104-1, 104-2, 104-N can be formed between a first layer of a substrate 222-1 and a second layer of a substrate 222-2 as referenced in FIG. 2.

Forming the first set of conductive nodes and the second set of conductive nodes can include forming a conductive material into a pillar or similar shape to allow the conductive traces to be connected to the first set of conductive nodes and/or the second set of conductive nodes. In some embodiments, the conductive material can allow an electrical current to pass from a first edge of a conductive node to a second edge of the conductive node.

At 574, the method 570 can include forming a plurality of conductive traces to connect the first set of conductive nodes to the second set of conductive nodes such that a coil is formed between the first layer and the second layer of a memory package. As described herein, the coil can be formed between the first layer 222-1 of a substrate and the second layer 222-2 of a substrate as referenced in FIG. 2. In these embodiments, the plurality of conductive traces can be the conductive traces 112 as referenced in FIG. 2. The formed conductive nodes and formed conductive traces can be utilized to form a conductive node induction apparatus 100 as referenced in FIG. 1. For example, the plurality of conductive traces can be formed of a conductive material to allow an electrical current to pass from a first conductive node to a second conductive node.

At 576, the method 570 can include forming a plurality of bond traces to connect the first set of conductive nodes to the second set of conductive nodes such that a bond wire is formed on an exterior surface of the first layer of the memory package. As described herein, a bond trace 331 can be formed to connect a first conductive node 102-1 to a second conductive node 104-1 as referenced in FIG. 3. In this way, the bond trace 331 is utilized to form a bond wire loop area 333-2 to generate an inductance as referenced in FIG. 3. The plurality of bond traces can be formed of a conductive material that is the same or similar conductive material as utilized to form the conductive nodes and/or the conductive traces.

In some embodiments, the method 570 includes forming the plurality of the bond traces includes forming a loop area (e.g., bond wire loop area 333-2 as referenced in FIG. 3, etc.) that extends beyond the first set of conductive nodes and the second set of conductive nodes. In some embodiments, forming the plurality of bond traces includes depositing a dielectric material on the exterior surface of the first layer of the memory package and forming the plurality of bond traces on the dielectric material. As described herein, the dielectric material or non-conductive material can be utilized to form the bond wire into a particular shape utilizing a plurality of transition positions. For example, the particular shape is described in reference to FIG. 3.

As described herein, in some embodiments, the plurality of bond traces includes a plurality of parallel bond traces that couples a particular conductive node from the first set of conductive nodes to a corresponding conductive node from the second set of conductive nodes. In these embodiments, the plurality of bond traces extend a first distance from the exterior surface of the memory package to a first position between the first set of conductive nodes and the second set of conductive nodes and extend a second distance from the exterior surface of the memory package to a second position between the first set of conductive nodes and the second set of conductive nodes. In these embodiments, the second distance is a peak position of a loop area formed by the plurality of bond traces.

At 578, the method 570 can include providing current to the first set of conductive nodes and the second set of conductive nodes to: provide current through the first set of conductive traces and the second set of conductive traces to generate a first inductance between the first set of conductive nodes and the second set of conductive nodes, and provide current through the plurality of bond traces to generate a second inductance between the first set of conductive nodes and the second set of conductive nodes.

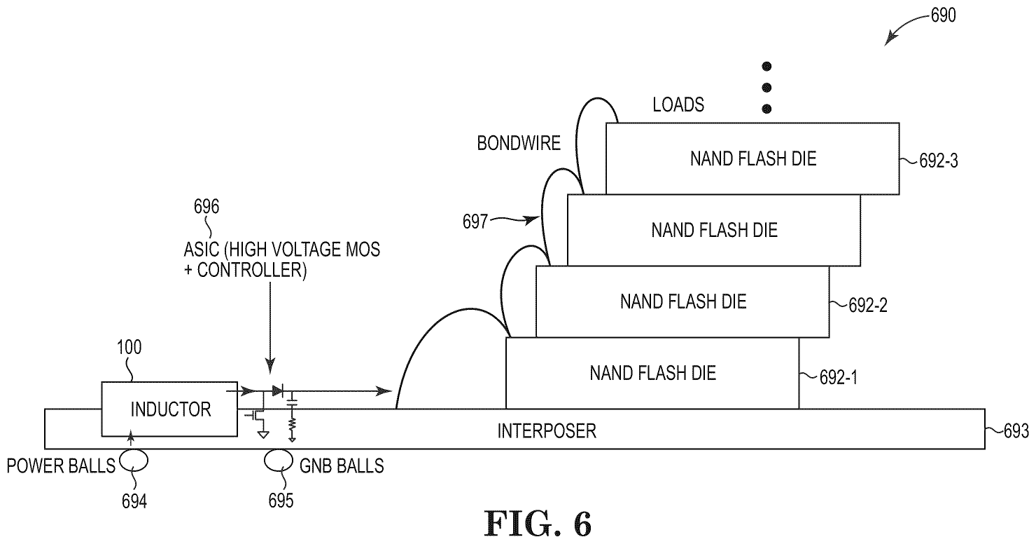

FIG. 6 illustrates a memory system 690 utilizing a bond wire induction apparatus 100 in accordance with a number of embodiments of the present disclosure. As described herein, the bond wire induction apparatus 100 can be utilized by a boost converter 594 that can be utilized by a memory device. The memory system 590 can include a dynamic random access memory (DRAM) 591, a negative-and (NAND) memory device 592, and an interposer 593. As used herein, an interposer 593 can be an electrical interface routing between one socket or connection to another.

In some embodiments, the system 590 can include a controller 595 of a memory device (e.g., DRAM 591, NAND memory device 592, etc.) coupled to an output of a bond wire induction apparatus 100. As described further herein, the bond wire induction apparatus 100 includes In this specific example, the bond wire induction apparatus 100 is configured to receive signaling having a first voltage value associated therewith, and apply, via the interposer 593, signaling having a second voltage value associated therewith to the controller 595. That is, a first portion of bond wire induction apparatus 100 can be embedded within a substrate of the system 590 and a second portion of the bond wire induction apparatus 100 can be positioned outside the substrate of the system 590.

In some embodiments, the bond wire induction apparatus 100 can be utilized by the boost converter 594 and/or charge pumps 597 to alter an input voltage to an increased output voltage. In some embodiments, the boost converter 594 includes the bond wire induction apparatus 100, a high-voltage metal-oxide semiconductor (MOS), and/or a controller 595. As described herein, the system 590 can have size constraints for the bond wire induction apparatus 100. In this way, the bond wire induction apparatus 100 described herein can be formed within the size constraints while still providing the induction levels and Q-factor that can be utilized by the system 590.

Although shown in a particular sequence or order, unless otherwise specified, the order of the methods can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Similar (e.g., the same) elements or components between different figures may be identified by the use of same or similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of turns can refer to one or more turns. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements. Unless stated otherwise, where a single element is discussed, it is understood that all similar elements are referred to.

It should be recognized the term planar accounts for variations from “exactly” planar due to routine manufacturing, measuring, and/or assembly variations and that one of ordinary skill in the art would know what is meant by the term “planar.”

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. An apparatus, comprising:
a memory package comprising a substrate and a plurality of memory layers;
a plurality of conductive nodes connected by a plurality of conductive traces to form a first portion of an induction device, wherein the first portion of the inductive device comprises an inductive coil within at least two layers of the plurality of memory layers of the memory package; and
a plurality of bond traces to couple a first portion of the plurality of conductive nodes to a second portion of the plurality of conductive nodes to form a second portion of the inductive device, wherein the second portion of the inductive device comprises an inductive bond wire in a physical area that is physically outside the memory package.

2. The apparatus of claim 1, wherein the plurality of bond traces each include a plurality of parallel bond traces.

3. The apparatus of claim 1, wherein the plurality of bond traces form an arc above an aperture of the memory package.

4. The apparatus of claim 1, wherein the memory package includes a first portion along a first edge of the plurality of conductive nodes and a second portion along a second edge of the plurality of conductive nodes.

5. The apparatus of claim 4, wherein the first portion of the memory package separates a portion of the plurality of conductive traces from the plurality of bond traces.

6. The apparatus of claim 1, wherein the inductive coil generates a first quantity of induction and the inductive bond wire generates a second quantity of induction.

7. The apparatus of claim 6, wherein the first quantity of induction and the second quantity of induction are utilized to form a DC/DC boost converter circuit.

8. A system, comprising:
a controller resident on a memory device; and
an induction apparatus resident on the memory device, the induction apparatus comprising:
a first plurality of conductive nodes connected to a second plurality of conductive nodes by a plurality of conductive traces to form an inductive;
a plurality of bond traces to couple the first plurality of conductive nodes to the second plurality of conductive nodes to form an inductive bond wire; and
a memory package positioned between the plurality of conductive traces and the plurality of bond traces, wherein the induction apparatus is configured to:
receive signaling having a first voltage value associated therewith, and
apply signaling having a second voltage value associated therewith to the controller.

9. The system of claim 8, wherein the plurality of conductive traces generate a first inductance from the received signaling having the first voltage and the plurality of bond traces generate a second inductance from the received signaling having the first voltage.

10. The system of claim 9, wherein the signaling having the second voltage is generated as a result of the first inductance and the second inductance.

11. The system of claim 8, wherein the plurality of bond traces each include a plurality of parallel conductive traces.

12. The system of claim 8, wherein the memory package includes an aperture between a portion of the plurality of conductive traces and the plurality of bond traces.

13. The system of claim 12, wherein plurality of bond traces form a peak above the aperture of the memory package.

14. The system of claim 8, wherein a non-conductive material is positioned between the memory package and the plurality of bond traces.

15. A method, comprising:
forming a first set of conductive nodes and a second set of conductive nodes between a first layer and a second layer of a memory package;
forming a plurality of conductive traces to connect the first set of conductive nodes to the second set of conductive nodes such that a coil is formed between the first layer and the second layer of a memory package;
forming a plurality of bond traces to connect the first set of conductive nodes to the second set of conductive nodes such that a bond wire is formed on an exterior surface of the first layer of the memory package; and
providing current to the first set of conductive nodes and the second set of conductive nodes to:
provide current through the first set of conductive traces and the second set of conductive traces to generate a first inductance between the first set of conductive nodes and the second set of conductive nodes; and
provide current through the plurality of bond traces to generate a second inductance between the first set of conductive nodes and the second set of conductive nodes.

16. The method of claim 15, wherein forming the plurality of bond traces includes depositing a dielectric material on the exterior surface of the first layer of the memory package and forming the plurality of bond traces on the dielectric material.

17. The method of claim 15, wherein the plurality of bond traces includes a plurality of parallel bond traces that couples a particular conductive node from the first set of conductive nodes to a corresponding conductive node from the second set of conductive nodes.

18. The method of claim 17, wherein the plurality of bond traces extend a first distance from the exterior surface of the memory package to a first position between the first set of conductive nodes and the second set of conductive nodes and extend a second distance from the exterior surface of the memory package to a second position between the first set of conductive nodes and the second set of conductive nodes.

19. The method of claim 18, wherein the second distance is a peak position of a loop area formed by the plurality of bond traces.

20. The method of claim 15, wherein forming the plurality of the bond traces includes forming a loop area that extends beyond the first set of conductive nodes and the second set of conductive nodes.
